(19) United States
(12) Patent Application Publication
(10) Pub. No.: US 2026/0122902 A1
(43) Pub. Date: Apr. 30, 2026

(54) THREE-DIMENSIONAL MEMORY DEVICE WITH DIVIDED DRAIN SELECT GATE LINES AND METHOD FOR FORMING THE SAME

(71) Applicant: YANGTZE MEMORY TECHNOLOGIES CO., LTD., Wuhan (CN)

(72) Inventors: Tingting GAO, Wuhan (CN); Zhiliang Xia, Wuhan (CN); Xiaoxin Liu, Wuhan (CN); Xiaolong Du, Wuhan (CN); Changzhi Sun, Wuhan (CN)

(73) Assignee: YANGTZE MEMORY TECHNOLOGIES CO., LTD., Wuhan (CN)

(21) Appl. No.: 19/432,279

(22) Filed: Dec. 24, 2025

Related U.S. Application Data
(63) Continuation of application No. 17/483,049, filed on Sep. 23, 2021.
Application No. 17/483,049 is a continuation of application No. PCT/CN2021/101146, filed on Jun. 21, 2021.

(51) Int. Cl. H10B 43/35; H10B 41/10; H10B 41/27; H10B 41/35; H10B 43/10; H10B 43/27

(52) U.S. Cl. CPC H10B 43/35; H10B 41/10; H10B 41/27; H10B 41/35; H10B 43/10; H10B 43/27

(57) ABSTRACT

A three-dimensional (3D) memory device includes a doped semiconductor layer, a stack structure, a channel structure, and a semiconductor structure. The stack structure includes a plurality of word lines and a select gate line formed on the doped semiconductor layer. The channel structure extends through the plurality of word lines along a first direction and in contact with the doped semiconductor layer. The semiconductor structure extends through the select gate line along the first direction and in contact with the channel structure. The select gate line extends along a second direction perpendicular to the first direction, and the drain select gate line around the semiconductor structure is insulated from the drain select gate line around an adjacent semiconductor structure. A width of the semiconductor structure is less than a width of the channel structure.

### CROSS-REFERENCE TO RELATED APPLICATIONS

This application is a continuation of U.S. application Ser. No. 17/483,049, filed on Sep. 23, 2021, which is a continuation of International Application No. PCT/CN2021/101146, filed on Jun. 21, 2021, both of which are incorporated herein by reference in their entirety.

### BACKGROUND

The present disclosure relates to memory devices and methods for forming memory devices.

Planar memory cells are scaled to smaller sizes by improving process technology, circuit design, programming algorithm, and fabrication process. However, as feature sizes of the memory cells approach a lower limit, planar process and fabrication techniques become challenging and costly. As a result, memory density for planar memory cells approaches an upper limit.

A three-dimensional (3D) memory architecture can address the density limitation in planar memory cells. The 3D memory architecture includes a memory array and peripheral circuits for facilitating operations of the memory array.

### SUMMARY

In one aspect, a 3D memory device is disclosed. The 3D memory device includes a doped semiconductor layer, a stack structure, a channel structure, and a semiconductor structure. The stack structure includes a plurality of word lines and a select gate line formed on the doped semiconductor layer. The channel structure extends through the plurality of word lines along a first direction and in contact with the doped semiconductor layer. The semiconductor structure extends through the select gate line along the first direction and in contact with the channel structure. The select gate line extends along a second direction perpendicular to the first direction, and the select gate line around the semiconductor structure is insulated from the select gate line around an adjacent semiconductor structure. A width of the semiconductor structure is less than a width of the channel structure.

In another aspect, a system is disclosed. The system includes a 3D memory device configured to store data and a memory controller. The 3D memory device includes a doped semiconductor layer, a stack structure, a channel structure, and a semiconductor structure. The stack structure includes a plurality of word lines and a select gate line formed on the doped semiconductor layer. The channel structure extends through the plurality of word lines along a first direction and in contact with the doped semiconductor layer. The semiconductor structure extends through the select gate line along the first direction and in contact with the channel structure. The select gate line extends along a second direction perpendicular to the first direction, and the select gate line around the semiconductor structure is insulated from the drain select gate line around an adjacent semiconductor structure. A width of the semiconductor structure is less than a width of the channel structure. The memory controller is coupled to the 3D memory device and is configured to control operations of the channel structure through the select gate line and the word lines.

In still another aspect, a method for forming a 3D memory device is disclosed. A first dielectric stack including a plurality of first dielectric layers and a plurality of first sacrificial layers interleaved on a doped semiconductor layer is formed. A plurality of channel structures extending vertically through the first dielectric stack are formed. A second dielectric stack including a plurality of second dielectric layers and a plurality of second sacrificial layers interleaved is formed on the first dielectric stack and the plurality of channel structures. An insulation layer is formed penetrating the second dielectric stack, and the second dielectric stack is separated into a first portion and a second portion by the insulation layer. A first semiconductor structure extending vertically through the first portion of the second dielectric stack is formed. A second semiconductor structure extending vertically through the second portion of the second dielectric stack is formed. The plurality of first sacrificial layers and the plurality of second sacrificial layers are replaced with a plurality of conductive layers.

In yet another aspect, a method for forming a 3D memory device is disclosed. A first stack structure including a plurality of word lines is formed on a doped semiconductor layer. A plurality of channel structures extending vertically through the first stack structure are formed. A second stack structure including a select gate line is formed on the first stack structure and the plurality of channel structures. An insulation layer is formed penetrating the second stack structure, and the second dielectric stack is separated into a first portion and a second portion by the insulation layer. The first portion and the second portion are electrically insulated. A first semiconductor structure extending vertically through the first portion of the second stack structure is formed. A second semiconductor structure extending vertically through the second portion of the second stack structure is formed.

### BRIEF DESCRIPTION OF THE DRAWINGS

The accompanying drawings, which are incorporated herein and form a part of the specification, illustrate aspects of the present disclosure and, together with the description, further serve to explain the present disclosure and to enable a person skilled in the pertinent art to make and use the present disclosure.

FIG. 1 illustrates a cross-section of an exemplary 3D memory device, according to some aspects of the present disclosure.

FIGS. 2A-2B illustrates top plans of an exemplary 3D memory device, according to some aspects of the present disclosure.

FIGS. 3-9 illustrate cross-sections of an exemplary 3D memory device at different stages of a manufacturing process, according to some aspects of the present disclosure.

FIG. 10 illustrates a flowchart of an exemplary method for forming a 3D memory device, according to some aspects of the present disclosure.

FIG. 11 illustrates a flowchart of another exemplary method for forming a 3D memory device, according to some aspects of the present disclosure.

FIG. 12 illustrates a block diagram of an exemplary system having a memory device, according to some aspects of the present disclosure.

FIG. 13A illustrates a diagram of an exemplary memory card having a memory device, according to some aspects of the present disclosure.

FIG. 13B illustrates a diagram of an exemplary solid-state drive (SSD) having a memory device, according to some aspects of the present disclosure.

The present disclosure will be described with reference to the accompanying drawings.

### DETAILED DESCRIPTION

Although specific configurations and arrangements are discussed, it should be understood that this is done for illustrative purposes only. As such, other configurations and arrangements can be used without departing from the scope of the present disclosure. Also, the present disclosure can also be employed in a variety of other applications. Functional and structural features as described in the present disclosures can be combined, adjusted, and modified with one another and in ways not specifically depicted in the drawings, such that these combinations, adjustments, and modifications are within the scope of the present discloses.

In general, terminology may be understood at least in part from usage in context. For example, the term “one or more” as used herein, depending at least in part upon context, may be used to describe any feature, structure, or characteristic in a singular sense or may be used to describe combinations of features, structures or characteristics in a plural sense. Similarly, terms, such as “a,” “an,” or “the,” again, may be understood to convey a singular usage or to convey a plural usage, depending at least in part upon context. In addition, the term “based on” may be understood as not necessarily intended to convey an exclusive set of factors and may, instead, allow for existence of additional factors not necessarily expressly described, again, depending at least in part on context.

It should be readily understood that the meaning of “on,” “above,” and “over” in the present disclosure should be interpreted in the broadest manner such that “on” not only means “directly on” something but also includes the meaning of “on” something with an intermediate feature or a layer therebetween, and that “above” or “over” not only means the meaning of “above” or “over” something but can also include the meaning it is “above” or “over” something with no intermediate feature or layer therebetween (i.e., directly on something).

Further, spatially relative terms, such as “beneath,” “below,” “lower,” “above,” “upper,” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations), and the spatially relative descriptors used herein may likewise be interpreted accordingly.

As used herein, the term “layer” refers to a material portion including a region with a thickness. A layer can extend over the entirety of an underlying or overlying structure or may have an extent less than the extent of an underlying or overlying structure. Further, a layer can be a region of a homogeneous or inhomogeneous continuous structure that has a thickness less than the thickness of the continuous structure. For example, a layer can be located between any pair of horizontal planes between, or at, a top surface and a bottom surface of the continuous structure. A layer can extend horizontally, vertically, and/or along a tapered surface. A substrate can be a layer, can include one or more layers therein, and/or can have one or more layer thereupon, thereabove, and/or therebelow. A layer can include multiple layers. For example, an interconnect layer can include one or more conductor and contact layers (in which interconnect lines and/or via contacts are formed) and one or more dielectric layers.

As used herein, the term “substrate” refers to a material onto which subsequent material layers are added. The substrate itself can be patterned. Materials added on top of the substrate can be patterned or can remain unpatterned. Furthermore, the substrate can include a wide array of semiconductor materials, such as silicon, germanium, gallium arsenide, indium phosphide, etc. Alternatively, the substrate can be made from an electrically non-conductive material, such as a glass, a plastic, or a sapphire wafer.

As used herein, the term “3D memory device” refers to a semiconductor device with vertically oriented strings of memory cell transistors (referred to herein as “memory strings,” such as NAND memory strings) on a laterally-oriented substrate so that the memory strings extend in the vertical direction with respect to the substrate. As used herein, the term “vertical/vertically” means nominally perpendicular to the lateral surface of a substrate.

In some 3D memory devices, such as 3D NAND memory devices, a stack of gate electrodes may be arranged over a substrate, with a plurality of semiconductor channels through and intersecting word lines, into the implanted substrate. The bottom/lower gate electrode or electrodes function as source select gate lines, which are also called bottom select gates (BSG) in some cases. The top/upper gate electrode or electrodes function as drain select gate lines, which are also called top select gates (TSG) in some cases. The gate electrodes between the top/upper select gate electrodes and the bottom/lower gate electrodes function as word lines (WLs). The intersection of a word line and a semiconductor channel forms a memory cell.

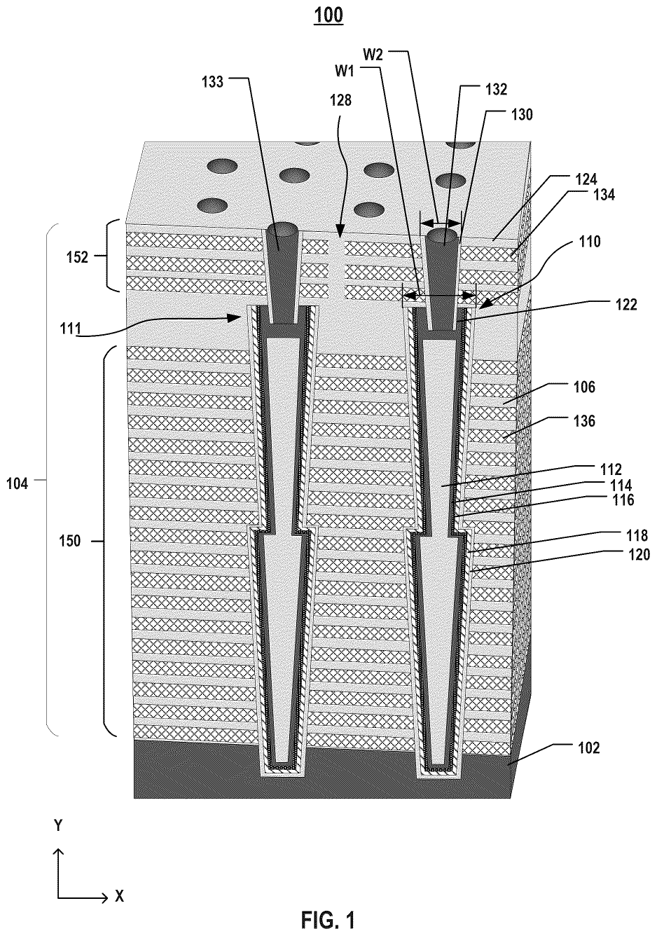

FIG. 1 illustrates a cross-section of an exemplary 3D memory device 100, according to some aspects of the present disclosure. 3D memory device 100 may include a substrate 102, which is a doped semiconductor layer and may include silicon (e.g., single crystalline silicon), silicon germanium (SiGe), gallium arsenide (GaAs), germanium (Ge), silicon on insulator (SOI), germanium on insulator (GOI), or any other suitable materials. In some implementations, substrate 102 is a thinned substrate (e.g., a semiconductor layer), which was thinned by grinding, etching, chemical mechanical polishing (CMP), or any combination thereof. It is noted that x and y axes are included in FIG. 1 to further illustrate the spatial relationship of the components in 3D memory device 100. Substrate 102 of 3D memory device 100 includes two lateral surfaces (e.g., a top surface and a bottom surface) extending laterally in the x-direction (i.e., the lateral direction). As used herein, whether one component (e.g., a layer or a device) is “on,” “above,” or “below” another component (e.g., a layer or a device) of a 3D memory device (e.g., 3D memory device 100) is determined relative to the substrate of the 3D memory device (e.g., substrate 102) in the y-direction (i.e., the vertical direction) when the substrate is positioned in the lowest plane of the 3D memory device in the y-direction. The same notion for describing spatial relationships is applied throughout the present disclosure.

3D memory device 100 may be part of a monolithic 3D memory device. The term “monolithic” means that the components (e.g., the peripheral device and memory array device) of the 3D memory device are formed on a single substrate. For monolithic 3D memory devices, the fabrication encounters additional restrictions due to the convolution of the peripheral device processing and the memory array device processing. For example, the fabrication of the memory array device (e.g., NAND memory strings) is constrained by the thermal budget associated with the peripheral devices that have been formed or to be formed on the same substrate.

Alternatively, 3D memory device 100 may be part of a non-monolithic 3D memory device, in which components (e.g., the peripheral device and memory array device) may be formed separately on different substrates and then bonded, for example, in a face-to-face manner. In some implementations, the memory array device substrate (e.g., substrate 102) remains as the substrate of the bonded non-monolithic 3D memory device, and the peripheral device (e.g., including any suitable digital, analog, and/or mixed-signal peripheral circuits used for facilitating the operation of 3D memory device 100, such as page buffers, decoders, and latches; not shown) is flipped and faces down toward the memory array device (e.g., NAND memory strings) for hybrid bonding. It is understood that in some implementations, the memory array device substrate (e.g., substrate 102) is flipped and faces down toward the peripheral device (not shown) for hybrid bonding, so that in the bonded non-monolithic 3D memory device, the memory array device is above the peripheral device. The memory array device substrate (e.g., substrate 102) may be a thinned substrate (which is not the substrate of the bonded non-monolithic 3D memory device), and the back-end-of-line (BEOL) interconnects of the non-monolithic 3D memory device may be formed on the backside of the thinned memory array device substrate.

In some implementations, 3D memory device 100 is a NAND Flash memory device in which memory cells are provided in the form of an array of NAND memory strings each extending vertically above substrate 102. As shown in FIG. 1, 3D memory device 100 may include a stack structure 104, including a first stack structure 150 and a second stack structure 152, formed on substrate 102, and the NAND memory string may include a channel structure 110 extending vertically through first stack structure 150 in the y-direction. First stack structure 150 includes interleaved conductive layers 136 and first dielectric layers 106, and conductive layers 136 may form a plurality of word lines. Second stack structure 152 includes interleaved conductive layers 134 and second dielectric layers 124, and conductive layers 134 may form at least one drain select gate line.

Channel structure 110 may include a channel hole filled with semiconductor materials (e.g., as a semiconductor channel 114) and dielectric materials (e.g., as a memory film). In some implementations, semiconductor channel 114 includes silicon, such as amorphous silicon, polysilicon, or single crystalline silicon. In some implementations, the memory film is a composite layer including a tunneling layer 116, a storage layer 118 (also known as a “charge trap layer”), and a blocking layer 120. In some implementations, the remaining space of channel structure 110 may be partially or fully filled with a filling layer 112 including dielectric materials, such as silicon oxide. Channel structure 110 may have a cylinder shape (e.g., a pillar shape). In some implementations, channel structure 110 may be formed by stacking more than one cylinder structure, as shown in FIG. 1. Filling layer 112, semiconductor channel 114, tunneling layer 116, storage layer 118, and blocking layer 120 are arranged radially from the center toward the outer surface of the pillar in this order, according to some implementations. Tunneling layer 116 may include silicon oxide, silicon oxynitride, or any combination thereof. Storage layer 118 may include silicon nitride, silicon oxynitride, silicon, or any combination thereof. Blocking layer 120 may include silicon oxide, silicon oxynitride, high dielectric constant (high-k) dielectrics, or any combination thereof. In one example, the memory film may include a composite layer of silicon oxide/silicon oxynitride (or silicon nitride)/silicon oxide (ONO).

In some implementations, channel structure 110 may further include a channel contact (not shown), or called semiconductor plug, in a lower portion (e.g., at the lower end) of channel structure 110. As used herein, the “upper end” of a component (e.g., channel structure 110) is the end farther away from substrate 102 in the y-direction, and the “lower end” of the component (e.g., channel structure 110) is the end closer to substrate 102 in the y-direction when substrate 102 is positioned in the lowest plane of 3D memory device 100. The channel contact may include a semiconductor material, such as silicon, which is epitaxially grown from substrate 102 in any suitable directions. It is understood that in some implementations, the channel contact includes single crystalline silicon, the same material as substrate 102. In other words, the channel contact may include an epitaxially-grown semiconductor layer that is the same as the material of substrate 102. In some implementations, part of the channel contact is above the top surface of substrate 102 and in contact with semiconductor channel 114. The channel contact may function as a channel controlled by a source select gate of the NAND memory string. It is understood that in some implementations, 3D memory device 100 does not include the channel contact, as shown in FIG. 1.

In some implementations, channel structure 110 further includes a channel plug 122 in an upper portion (e.g., at the upper end) of channel structure 110. Channel plug 122 may be in contact with the upper end of semiconductor channel 114. Channel plug 122 may include semiconductor materials (e.g., polysilicon). By covering the upper end of channel structure 110 during the fabrication of 3D memory device 100, channel plug 122 may function as an etch stop layer to prevent etching of dielectrics filled in channel structure 110, such as silicon oxide and silicon nitride. In some implementations, channel plug 122 also functions as the drain of the NAND memory string.

The memory array device may include NAND memory strings that extend through interleaved conductive layers 136 and first dielectric layers 106, and the stacked conductive/dielectric layer pairs are also referred to as a memory stack. The memory array device may further include conductive layers 134 (the drain select gate line), and a semiconductor structure, e.g., a drain structure 132, may extend through the drain select gate line along the y-direction and in contact with channel structure 110. Specifically, drain structure 132 may directly contact channel plug 122. In some implementations, drain structure 132 and channel plug 122 may be formed by a same material. In some implementations, drain structure 132 may include semiconductor materials (e.g., polysilicon).

The word lines (conductive layers 136) may include conductive materials including, but not limited to, tungsten (W), cobalt (Co), copper (Cu), aluminum (Al), polysilicon, doped silicon, silicides, or any combination thereof. First dielectric layers 106 may include dielectric materials including, but not limited to, silicon oxide, silicon nitride, silicon oxynitride, or any combination thereof. In some implementations, each word line in stack structure 104 (e.g., a memory stack) functions as a gate conductor of memory cells in the NAND memory string. Conductive layers 136 may extend laterally coupling a plurality of memory cells. In some implementations, memory cell transistors in NAND memory string include semiconductor channel 114, memory film (including tunneling layer 116, storage layer 118, and blocking layer 120), and the word lines. The word lines (conductive layers 136) or the drain select gate line (conductive layers 134) may further include a gate conductor made from tungsten, adhesion layers including titanium/titanium nitride (Ti/TiN) or tantalum/tantalum nitride (Ta/TaN), and gate dielectric layers made from high-k dielectric materials.

As shown in FIG. 1, conductive layers 134 extend along the x-direction and are divided by an insulation structure 128. In some implementations, insulation structure 128 is formed by a dielectric material. Conductive layers 134 around drain structure 132 is electrically insulated from conductive layers 134 around an adjacent drain structure. Drain structure 132 may further include a blocking layer 130 formed between drain structure 132 and the drain select gate line. In some implementations, the width of drain structure 132 is W2, and W2 may be less than the width of channel structure 110, which is W1. Specifically, in some implementations, the width of drain structure 132 may be less than the width of channel plug 122.

Insulation structure 128 is used for electrically insulating the drain select gate line between two adjacent memory strings. By forming drain structure 132 on channel plug 122 and having a width smaller than channel plug 122, drain structure 132, blocking layer 130, and conductive layers 134 may form a regular metal-oxide semiconductor field-effect transistor (MOSFET), and the cutting windows to form insulation structure 128 may be increased as well. Therefore, the required distance for forming insulation structure 128 between two adjacent memory strings can be decreased and the density of memory strings can be increased.

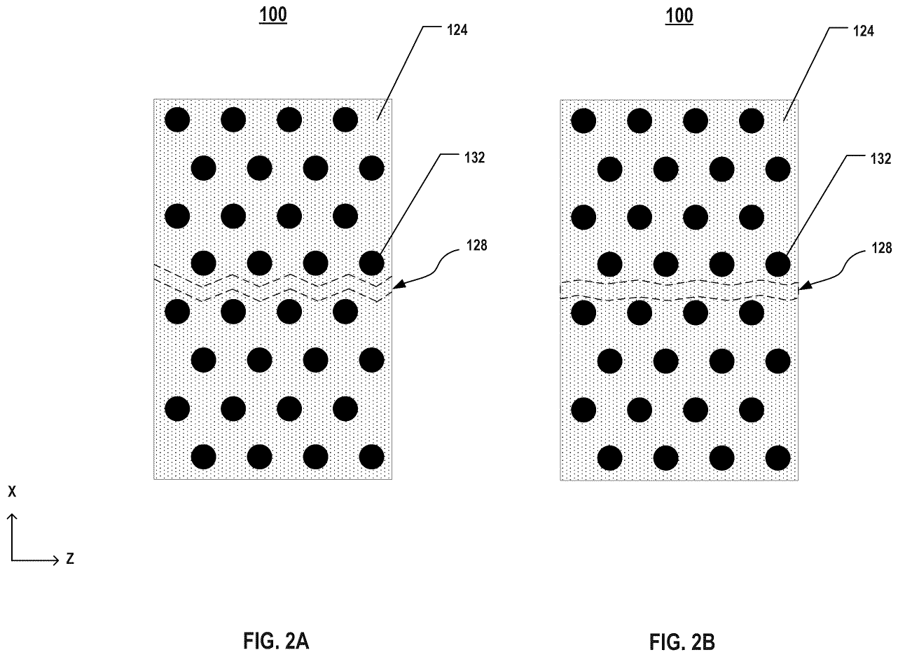

FIGS. 2A-2B illustrates top plans of 3D memory device 100, according to some aspects of the present disclosure. As shown in FIG. 2A, in some implementations, insulation structure 128 may be a zigzag structure in the top plan of 3D memory device 100. As shown in FIG. 2B, in some implementations, insulation structure 128 may be a waved structure in the top plan of 3D memory device 100. It is understood that, in some implementations, insulation structure 128 may be a straight line extending along the z-direction in the top plan of 3D memory device 100, and the design of forming insulation structure 128 in the zigzag structure or waved structure in the top plan of 3D memory device 100 may further decrease the required distance for forming insulation structure 128 between two adjacent memory strings.

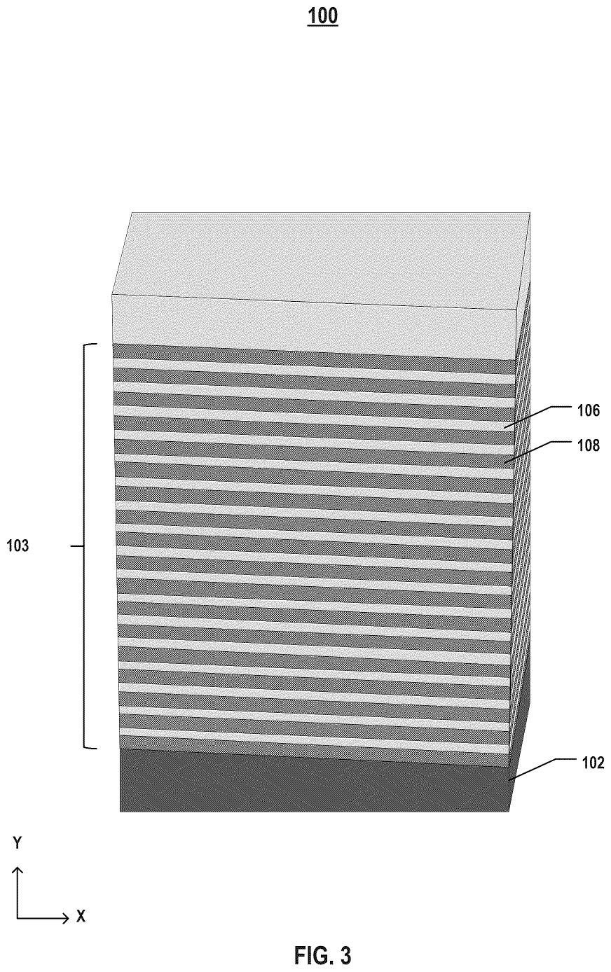

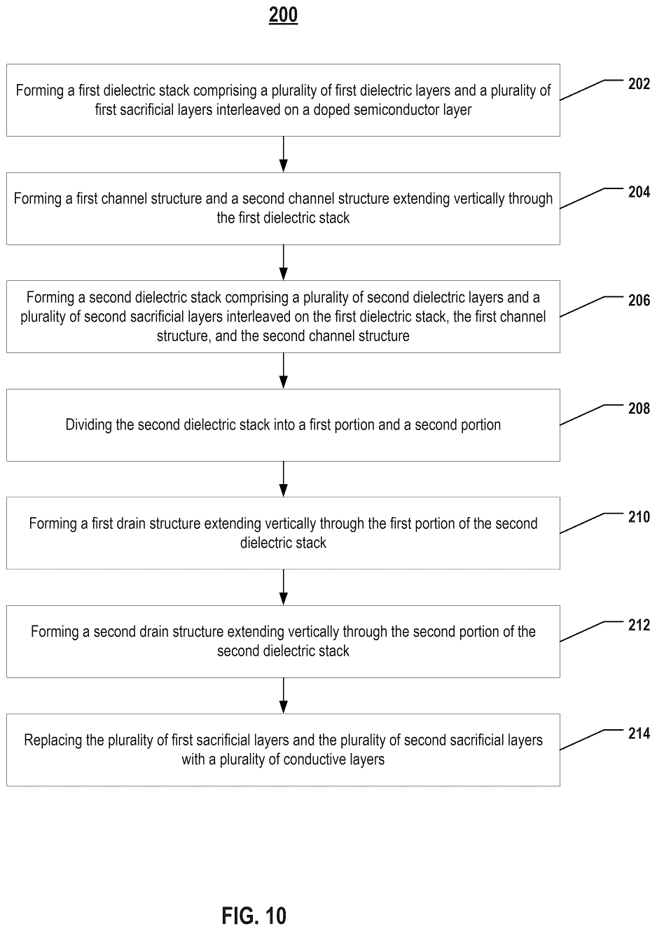

FIGS. 3-9 illustrate cross-sections of 3D memory device 100 at different stages of a manufacturing process, according to some aspects of the present disclosure. FIG. 10 illustrates a flowchart of an exemplary method 200 for forming 3D memory device 100, according to some aspects of the present disclosure.

For the purpose of better describing the present disclosure, the cross-sections of 3D memory device 100 in FIGS. 3-9 and method 200 in FIG. 10 will be discussed together. It is understood that the operations shown in method 200 are not exhaustive and that other operations may be performed as well before, after, or between any of the illustrated operations. Further, some of the operations may be performed simultaneously, or in a different order than shown in FIGS. 3-9 and FIG. 10.

As shown in FIG. 3 and operation 202 of FIG. 10, a first dielectric stack 103 is formed on substrate 102. First dielectric stack 103 includes first dielectric layers 106 and a plurality of first sacrificial layers 108 interleaved on substrate 102. In some implementations, substrate 102 may be a doped semiconductor layer. The dielectric/sacrificial layer pairs include interleaved first dielectric layers 106 and first sacrificial layers 108 extending in the x-direction. In some implementations, each dielectric layer 106 may include a layer of silicon oxide, and each sacrificial layer 108 may include a layer of silicon nitride. First dielectric stack 103 may be formed by one or more thin film deposition processes including, but not limited to, chemical vapor deposition (CVD), physical vapor deposition (PVD), atomic layer deposition (ALD), or any combination thereof. In some implementations, a pad oxide layer (not shown) is formed between substrate 102 and first dielectric stack 103 by depositing dielectric materials, such as silicon oxide, on substrate 102.

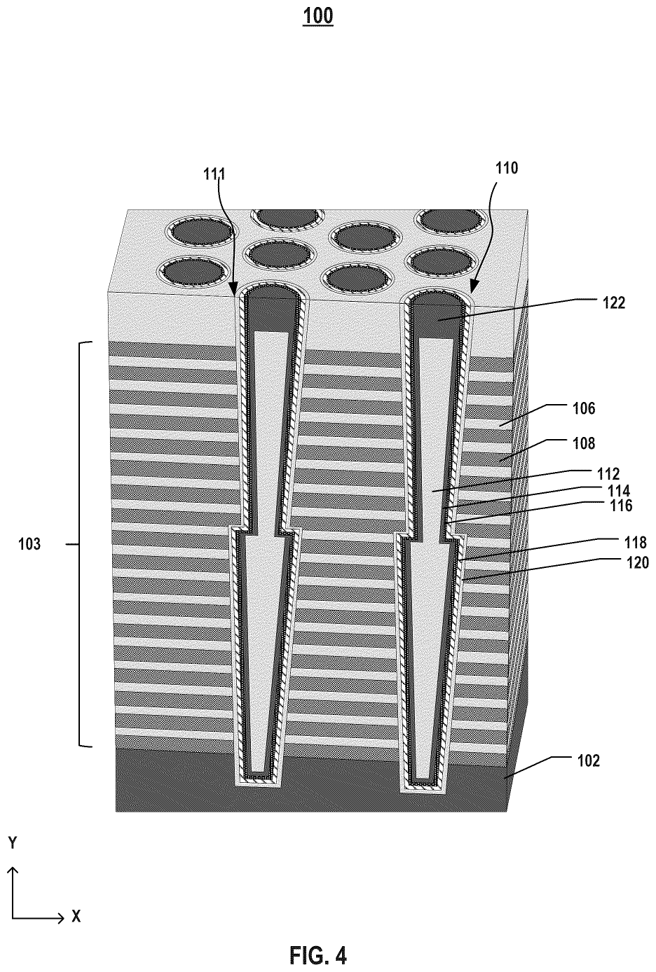

Then, as shown in FIG. 4 and operation 204 of FIG. 10, a first channel structure 110 and a second channel structure 111 are formed extending vertically through first dielectric stack 103 in the y-direction. In some implementations, an etch process may be performed to form a plurality of channel holes in first dielectric stack 103 that extends vertically through the interleaved dielectric/sacrificial layers. In some implementations, fabrication processes for forming the channel holes may include wet etching and/or dry etching, such as deep reactive ion etching (DRIE). In some implementations, the channel holes may extend further into the top portion of substrate 102. The etch process through first dielectric stack 103 may not stop at the top surface of substrate 102 and may continue to etch part of substrate 102. After the formation of the channel holes, an epitaxial operation, e.g., a selective epitaxial growth operation, may be performed to form the channel contacts on the bottom of the channel holes. Then, the memory film, including tunneling layer 116, storage layer 118, and blocking layer 120, and semiconductor channel 114 can be formed on the channel contact. Channel plug 122 may be further formed on the memory film and semiconductor channel 114. In some implementations, channel structures 110 and 111 may not include the channel contact, as shown in FIG. 4.

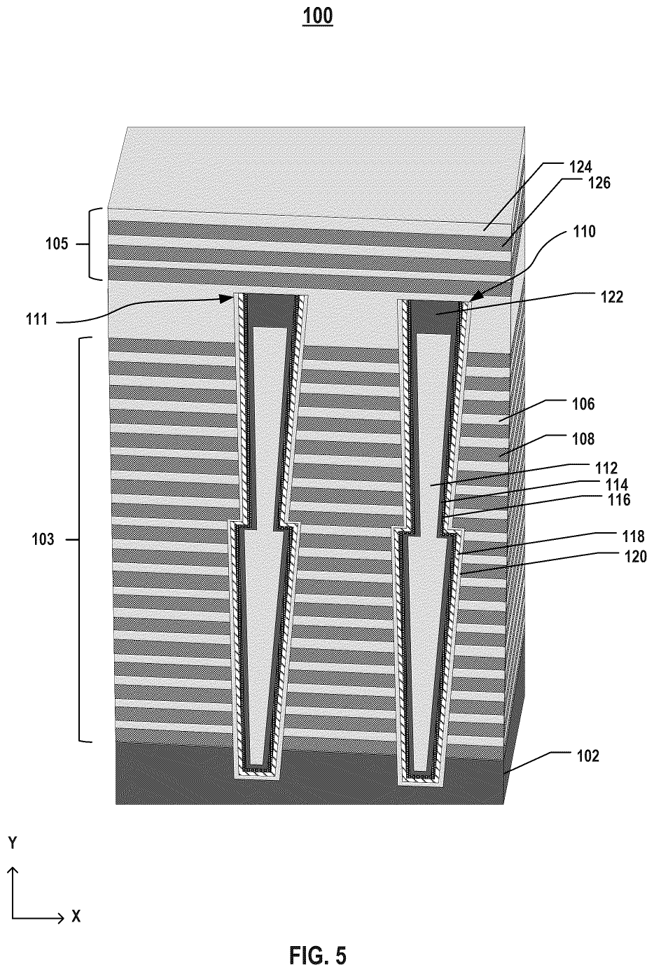

As shown in FIG. 5 and operation 206 of FIG. 10, a second dielectric stack 105 is formed on first dielectric stack 103 covering first dielectric stack 103, first channel structure 110, and second channel structure 111. Second dielectric stack 105 includes second dielectric layers 124 and a plurality of second sacrificial layers 126. In some implementations, first dielectric layers 106 and second dielectric layers 124 may be formed by a same material. In some implementations, first sacrificial layers 108 and second sacrificial layers 126 may be formed by a same material. In some implementations, second dielectric stack 105 may be formed by one or more thin film deposition processes including, but not limited to, CVD, PVD, ALD, or any combination thereof.

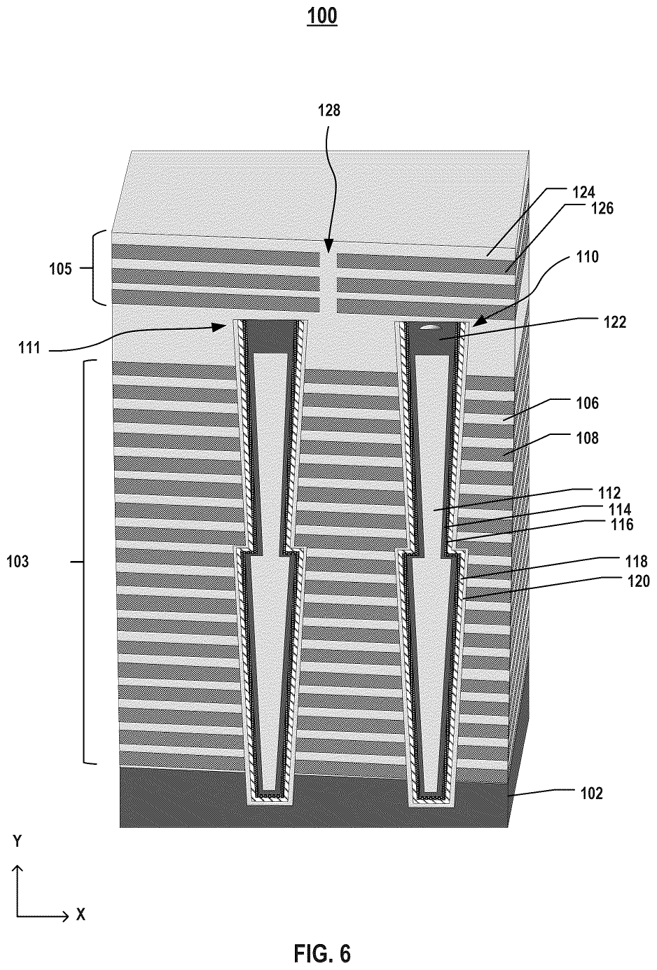

As shown in FIG. 6 and operation 208 of FIG. 10, second dielectric stack 105 is divided into a first portion and a second portion. In some implementations, an etch process may be performed to remove a portion of second dielectric stack 105 to form a list in second dielectric stack 105. Then, a dielectric layer may be formed in the slit to divide second dielectric stack 105 into two portions. In some implementations, the etch process forming the list may include dry etch, wet etch, or other suitable processes. The dielectric layer in the slit may be formed by CVD, PVD, ALD, or other suitable processes.

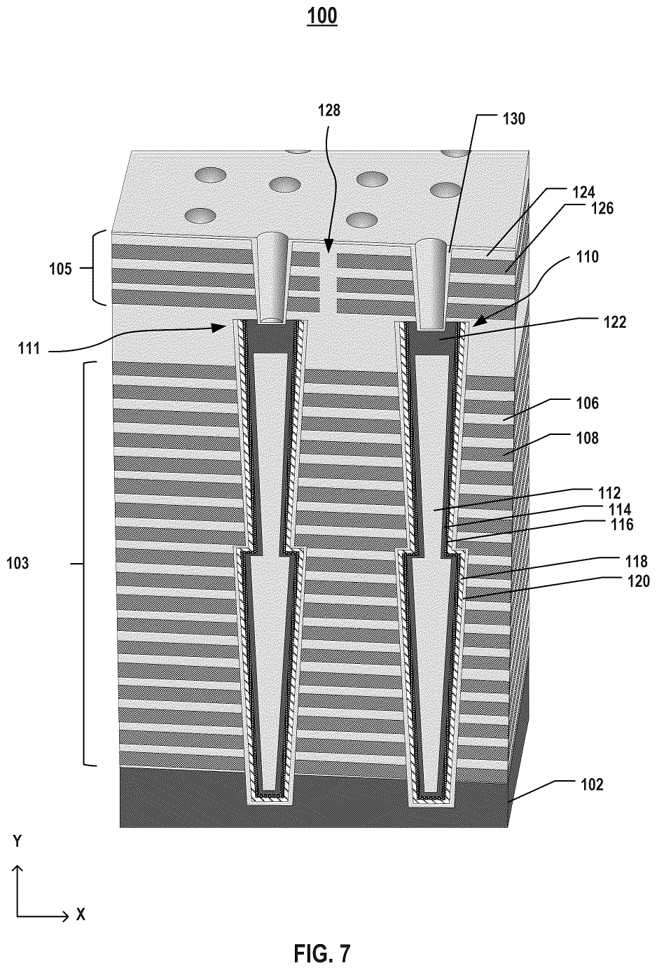

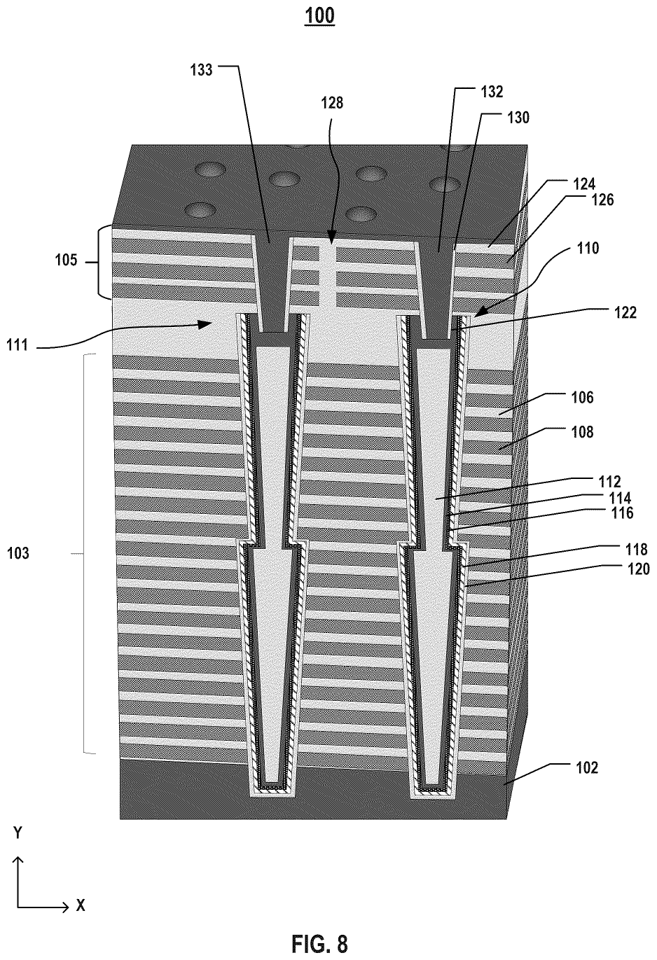

As shown in FIGS. 7 and 8 and operations 210 and 212 of FIG. 10, a first drain structure 132 is formed extending vertically through the first portion of second dielectric stack 105, and a second drain structure 133 is formed extending vertically through the second portion of second dielectric stack 105. In some implementations, first drain structure 132 and second drain structure 133 may be formed during a same operation. In some implementations, a first opening is formed in the first portion of second dielectric stack 105 to expose channel plug 122 of first channel structure 110, and a second opening is formed in the second portion of second dielectric stack 105 to expose channel plug 122 of second channel structure 111. In some implementations, the diameter of the first opening and the second opening is less than the width of first channel structure 110 and second channel structure 111. Then, blocking layer 130 is formed on sidewalls of the first opening and the second opening, as shown in FIG. 7. A semiconductor layer is formed in the first opening and the second opening in contact with channel plug 122. The semiconductor layer may fill in the first opening and the second opening and cover the top surface of second dielectric stack 105, as shown in FIG. 8. Then, a planarization process may be performed to remove the semiconductor layer above the second dielectric stack 105 to form first drain structure 132 and second drain structure 133. In some implementations, first drain structure 132 and second drain structure 133 may include semiconductor materials (e.g., polysilicon). In some implementations, first drain structure 132 and second drain structure 133 may be formed by CVD, PVD, ALD, or other suitable processes.

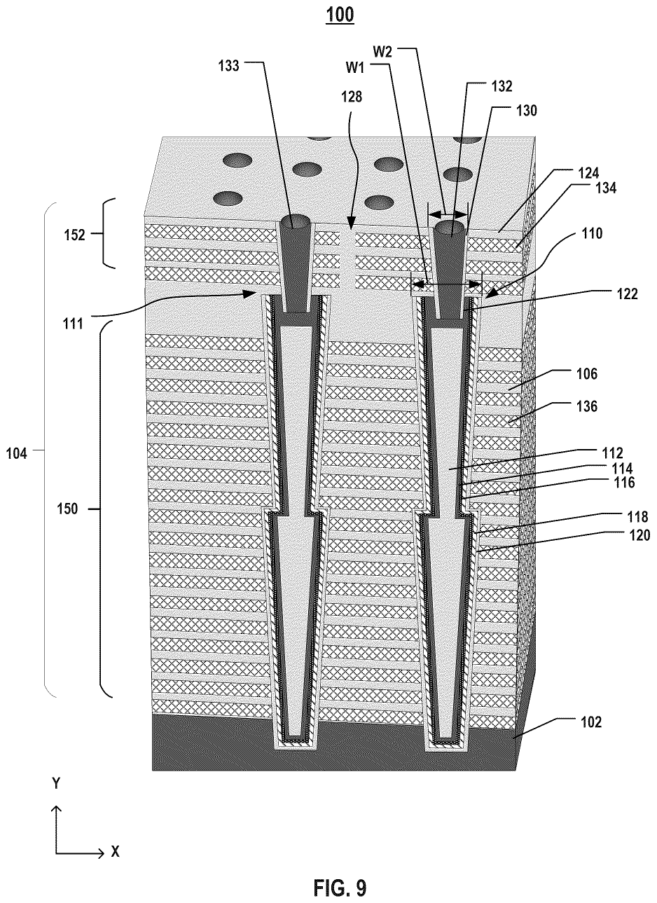

As shown in FIG. 9 and operations 214 of FIG. 10, first sacrificial layers 108 and second sacrificial layers 126 are replaced by conductive layers 136 and conductive layers 134. In some implementations, first sacrificial layers 108 and second sacrificial layers 126 may be removed by performing an etch process. In some implementations, the etch process may be a dry etch, a wet etch, or other suitable processes. After the removal of first sacrificial layers 108 and second sacrificial layers 126, a plurality of openings may be formed between first dielectric layers 106 and between second dielectric layers 124. Then, conductive layers 136 may be formed in the openings between first dielectric layers 106, and conductive layers 134 may be formed in the openings between second dielectric layers 124, as shown in FIG. 9. In some implementations, conductive layers 136 and conductive layers 134 may include a same material. In some implementations, conductive layers 136 and conductive layers 134 may include conductive materials including, but not limited to, W, Co, Cu, Al, polysilicon, doped silicon, silicides, or any combination thereof. In some implementations, conductive layers 136 and conductive layers 134 may be formed by CVD, PVD, ALD, or other suitable processes.

Conductive layers 134 extend along the x-direction and are divided by insulation structure 128. Conductive layers 134 around first drain structure 132 is electrically insulated from conductive layers 134 around second drain structure 133. In some implementations, the width of first drain structure 132 is W2, and W2 may be less than the width of first channel structure 110 (W1), and the width of second drain structure 133 (W2) may be also less than the width of second channel structure 111 (W1). Specifically, in some implementations, the width of first drain structure 132 and second drain structure 133 may be less than the width of channel plug 122.

Insulation structure 128 is used for electrically insulating the drain select gate line between two adjacent memory strings. By forming first drain structure 132 and second drain structure 133 on channel plug 122 and having the width smaller than channel plug 122, drain structures 132/133, blocking layer 130 and conductive layers 134 may form a regular MOSFET, and the cutting windows to form insulation structure 128 may be increased as well. Therefore, the required distance for forming insulation structure 128 between two adjacent memory strings can be decreased, and the density of memory strings can be increased.

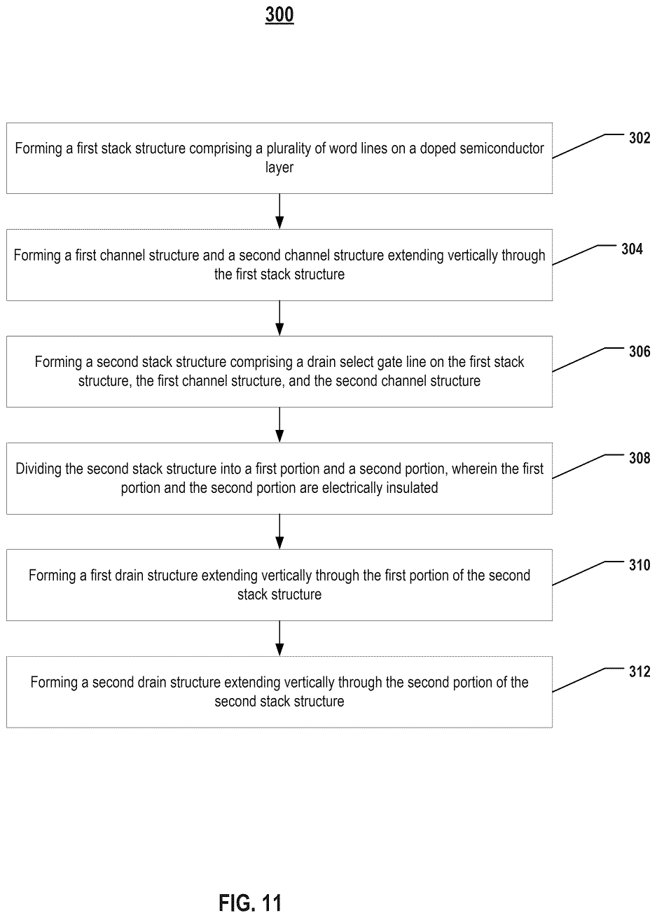

FIG. 11 illustrates a flowchart of another exemplary method 300 for forming a 3D memory device, according to some aspects of the present disclosure. Method 300 describes the operations to form word lines without forming and replacing the sacrificial layers. It is understood that the features of conductive layers 134 divided by insulation structure 128 are similar to the implementations of method 200, and the width of first drain structure 132 may be less than the width of first channel structure 110, and the width of second drain structure 133 may be less than the width of second channel structure 111.

As shown in operation 302 of FIG. 11, a first stack structure including a plurality of word lines is formed on a doped semiconductor layer. In some implementations, the word lines may be conductive layers 136 in FIG. 1, and the doped semiconductor layer may be substrate 102. Then, as shown in operation 304 of FIG. 11, a first channel structure and a second channel structure are formed extending vertically through the first stack structure. In some implementations, the first channel structure may be first channel structure 110, and the second channel structure may be second channel structure 111 in FIG. 1. As shown in operation 306 of FIG. 11, a second stack structure including a drain select gate line is formed on the first stack structure, the first channel structure, and the second channel structure. In some implementations, the second stack structure may be second stack structure 152 in FIG. 1, and the drain select gate line may be conductive layers 134. As shown in operation 308 of FIG. 11, the second stack structure is divided into a first portion and a second portion, and the first portion and the second portion are electrically insulated. In some implementations, a portion of the second stack structure may be removed to form a slit in the second stack structure, and a dielectric layer may be formed in the slit to form an insulation structure between the first portion and the second portion of the second stack structure.

As shown in operations 310 and 312 of FIG. 11, a first drain structure is formed extending vertically through the first portion of the second stack structure, and a second drain structure is formed extending vertically through the second portion of the second stack structure. In some implementations, the first drain structure may be first drain structure 132, and the second drain structure may be second drain structure 133 in FIG. 1.

The drain select gate lines extend along the x-direction and are divided by insulation structure 128. The drain select gate lines around first drain structure 132 are electrically insulated from the drain select gate lines around second drain structure 133. In some implementations, the width of first drain structure 132 may be less than the width of first channel structure 110, and the width of second drain structure 133 may be less than the width of second channel structure 111. Specifically, in some implementations, the width of first drain structure 132 and second drain structure 133 may be less than the width of channel plug 122. Insulation structure 128 is used for electrically insulating the drain select gate line between two adjacent memory strings. By forming first drain structure 132 and second drain structure 133 on channel plug 122 and having the width smaller than channel plug 122, the cutting windows to form insulation structure 128 may be increased. Therefore, the required distance for forming insulation structure 128 between two adjacent memory strings can be decreased, and the density of memory strings can be increased.

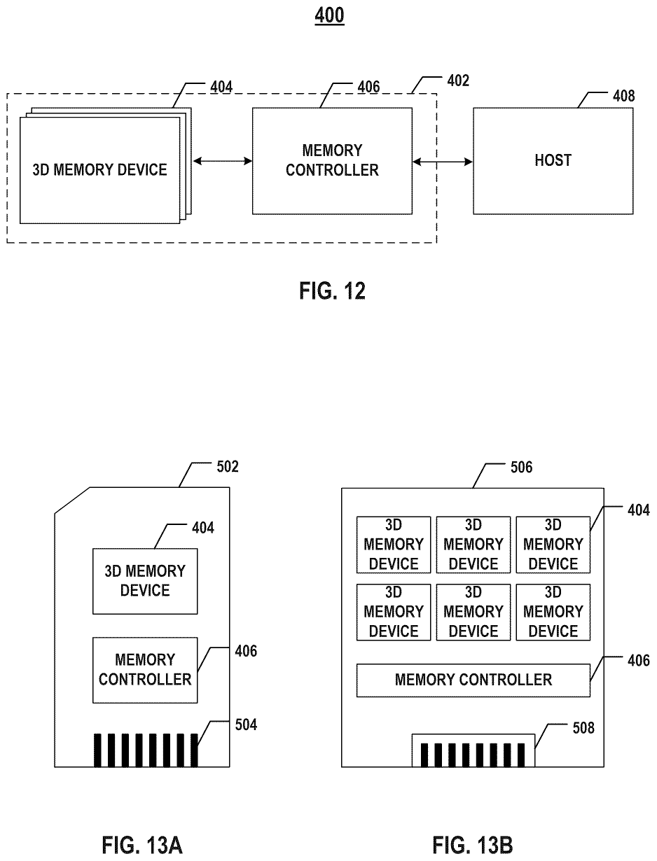

FIG. 12 illustrates a block diagram of an exemplary system 400 having a memory device, according to some aspects of the present disclosure. System 400 can be a mobile phone, a desktop computer, a laptop computer, a tablet, a vehicle computer, a gaming console, a printer, a positioning device, a wearable electronic device, a smart sensor, a virtual reality (VR) device, an argument reality (AR) device, or any other suitable electronic devices having storage therein. As shown in FIG. 12, system 400 can include a host 408 and a memory system 402 having one or more memory devices 404 and a memory controller 406. Host 408 can be a processor of an electronic device, such as a central processing unit (CPU), or a system-on-chip (SoC), such as an application processor (AP). Host 408 can be configured to send or receive data to or from memory devices 404.

Memory device 404 can be any memory device disclosed in the present disclosure. As disclosed above in detail, memory device 404, such as a NAND Flash memory device, may have a controlled and predefined discharge current in the discharge operation of discharging the bit lines. Memory controller 406 is coupled to memory device 404 and host 408 and is configured to control memory device 404, according to some implementations. Memory controller 406 can manage the data stored in memory device 404 and communicate with host 408. For example, memory controller 406 may be coupled to memory device 404, such as 3D memory device 100 described above, and memory controller 406 may be configured to control operations of channel structure 110 of 3D memory device 100 through drain select gate line 134 and/or select gate line. By forming first drain structure 132 and second drain structure 133 on channel plug 122 and having the width smaller than channel plug 122, the cutting windows to form insulation structure 128 may be increased. Therefore, the required distance for forming insulation structure 128 between two adjacent memory strings can be decreased and the density of memory strings can be increased.

In some implementations, memory controller 406 is designed for operating in a low duty-cycle environment like secure digital (SD) cards, compact Flash (CF) cards, universal serial bus (USB) Flash drives, or other media for use in electronic devices, such as personal computers, digital cameras, mobile phones, etc. In some implementations, memory controller 406 is designed for operating in a high duty-cycle environment SSDs or embedded multi-media-cards (eMMCs) used as data storage for mobile devices, such as smartphones, tablets, laptop computers, etc., and enterprise storage arrays. Memory controller 406 can be configured to control operations of memory device 404, such as read, erase, and program operations. Memory controller 406 can also be configured to manage various functions with respect to the data stored or to be stored in memory device 404 including, but not limited to bad-block management, garbage collection, logical-to-physical address conversion, wear leveling, etc. In some implementations, memory controller 406 is further configured to process error correction codes (ECCs) with respect to the data read from or written to memory device 404. Any other suitable functions may be performed by memory controller 406 as well, for example, formatting memory device 404. Memory controller 406 can communicate with an external device (e.g., host 408) according to a particular communication protocol. For example, memory controller 406 may communicate with the external device through at least one of various interface protocols, such as a USB protocol, an MMC protocol, a peripheral component interconnection (PCI) protocol, a PCI-express (PCI-E) protocol, an advanced technology attachment (ATA) protocol, a serial-ATA protocol, a parallel-ATA protocol, a small computer small interface (SCSI) protocol, an enhanced small disk interface (ESDI) protocol, an integrated drive electronics (IDE) protocol, a Firewire protocol, etc.

Memory controller 406 and one or more memory devices 404 can be integrated into various types of storage devices, for example, be included in the same package, such as a universal Flash storage (UFS) package or an eMMC package. That is, memory system 402 can be implemented and packaged into different types of end electronic products. In one example as shown in FIG. 13A, memory controller 406 and a single memory device 404 may be integrated into a memory card 502. Memory card 502 can include a PC card (PCMCIA, personal computer memory card international association), a CF card, a smart media (SM) card, a memory stick, a multimedia card (MMC, RS-MMC, MMCmicro), an SD card (SD, miniSD, microSD, SDHC), a UFS, etc. Memory card 502 can further include a memory card connector 504 coupling memory card 502 with a host (e.g., host 408 in FIG. 12). In another example as shown in FIG. 13B, memory controller 406 and multiple memory devices 404 may be integrated into an SSD 506. SSD 506 can further include an SSD connector 508 coupling SSD 506 with a host (e.g., host 408 in FIG. 12). In some implementations, the storage capacity and/or the operation speed of SSD 506 is greater than those of memory card 502.

According to one aspect of the present disclosure, a 3D memory device is disclosed. The 3D memory device includes a doped semiconductor layer, a stack structure, a channel structure, and a semiconductor structure. The stack structure includes a plurality of word lines and a select gate line formed on the doped semiconductor layer. The channel structure extends through the plurality of word lines along a first direction and in contact with the doped semiconductor layer. The semiconductor structure extends through the select gate line along the first direction and in contact with the channel structure. The select gate line extends along a second direction perpendicular to the first direction, and the select gate line around the semiconductor structure is insulated from the select gate line around an adjacent semiconductor structure. A width of the semiconductor structure is less than a width of the channel structure.

In some implementations, the semiconductor structure further includes a semiconductor layer and a blocking layer formed between the semiconductor layer and the select gate line. In some implementations, the channel structure further includes a channel plug, and the semiconductor structure is in contact with the channel plug. In some implementations, the channel plug and the semiconductor layer include a same material. In some implementations, the channel plug and the semiconductor layer are formed by polysilicon.

In some implementations, the select gate line around the semiconductor structure and the select gate line around the adjacent semiconductor structure are insulated by a dielectric layer. In some implementations, the dielectric layer includes a zigzag structure in a top plan of the 3D memory device. In some implementations, the dielectric layer includes a waved structure in a top plan of the 3D memory device. In some implementations, a width of the semiconductor structure is less than a width of the channel plug.

According to another aspect of the present disclosure, a system is disclosed. The system includes a 3D memory device configured to store data and a memory controller. The 3D memory device includes a doped semiconductor layer, a stack structure, a channel structure, and a semiconductor structure. The stack structure includes a plurality of word lines and a select gate line formed on the doped semiconductor layer. The channel structure extends through the plurality of word lines along a first direction and in contact with the doped semiconductor layer. The semiconductor structure extends through the select gate line along the first direction and in contact with the channel structure. The select gate line extends along a second direction perpendicular to the first direction, and the select gate line around the semiconductor structure is insulated from the select gate line around an adjacent semiconductor structure. A width of the semiconductor structure is less than a width of the channel structure. The memory controller is coupled to the 3D memory device and is configured to control operations of the channel structure through the select gate line and the word lines.

According to still another aspect of the present disclosure, a method for forming a 3D memory device is disclosed. A first dielectric stack including a plurality of first dielectric layers and a plurality of first sacrificial layers interleaved on a doped semiconductor layer is formed. A plurality of channel structures extending vertically through the first dielectric stack are formed. A second dielectric stack including a plurality of second dielectric layers and a plurality of second sacrificial layers interleaved is formed on the first dielectric stack and the plurality of channel structures. An insulation layer is formed penetrating the second dielectric stack, and the second dielectric stack is separated into a first portion and a second portion by the insulation layer. A first semiconductor structure extending vertically through the first portion of the second dielectric stack is formed. A second semiconductor structure extending vertically through the second portion of the second dielectric stack is formed. The plurality of first sacrificial layers and the plurality of second sacrificial layers are replaced with a plurality of conductive layers.

In some implementations, a portion of the second dielectric stack is removed to form a slit in the second dielectric stack, and the insulation layer is formed in the slit. In some implementations, a first opening is formed in the first portion of the second dielectric stack to expose a first channel plug of the channel structure, a blocking layer is formed on sidewalls of the first opening, and a semiconductor layer is formed in the first opening in contact with the first channel plug. In some implementations, a second opening is formed in the second portion of the second dielectric stack to expose a second channel plug of the channel structure, a blocking layer is formed on sidewalls of the second opening, and a semiconductor layer is formed in the second opening in contact with the second channel plug. In some implementations, the first semiconductor structure and the second semiconductor structure are formed during a same operation.

In some implementations, a width of the first semiconductor structure and a width of the second semiconductor structure are less than a width of the plurality of channel structures.

According to yet another aspect of the present disclosure, a method for forming a 3D memory device is disclosed. A first stack structure including a plurality of word lines is formed on a doped semiconductor layer. A plurality of channel structures extending vertically through the first stack structure are formed. A second stack structure including a select gate line is formed on the first stack structure and the plurality of channel structures. An insulation layer is formed penetrating the second dielectric stack, and the second dielectric stack is separated into a first portion and a second portion by the insulation layer. The first portion and the second portion are electrically insulated. A first semiconductor structure extending vertically through the first portion of the second stack structure is formed. A second semiconductor structure extending vertically through the second portion of the second stack structure is formed.

In some implementations, a portion of the second dielectric stack is removed to form a slit in the second dielectric stack, and the insulation layer is formed in the slit. In some implementations, a first opening is formed in the first portion of the second dielectric stack to expose a first channel plug of the channel structure, a blocking layer is formed on sidewalls of the first opening, and a semiconductor layer is formed in the first opening in contact with the first channel plug. In some implementations, a second opening is formed in the second portion of the second dielectric stack to expose a second channel plug of the channel structure, a blocking layer is formed on sidewalls of the second opening, and a semiconductor layer is formed in the second opening in contact with the second channel plug. In some implementations, the first semiconductor structure and the second semiconductor structure are formed during a same operation.

In some implementations, a width of the first semiconductor structure and a width of the second semiconductor structure are less than a width of the plurality of channel structures.

The foregoing description of the specific implementations can be readily modified and/or adapted for various applications. Therefore, such adaptations and modifications are intended to be within the meaning and range of equivalents of the disclosed implementations, based on the teaching and guidance presented herein.

The breadth and scope of the present disclosure should not be limited by any of the above-described exemplary implementations, but should be defined only in accordance with the following claims and their equivalents.

What is claimed is:

1. A three-dimensional (3D) memory device, comprising:
a doped semiconductor layer;
a stack structure comprising a plurality of word lines and a plurality of select gate lines formed on the doped semiconductor layer;
a channel structure extending through the plurality of word lines along a first direction and in contact with the doped semiconductor layer;
a semiconductor structure extending through the plurality of select gate lines along the first direction and in contact with the channel structure; and
a first dielectric layer extending through the plurality of select gate lines along the first direction,
wherein a portion of a sidewall of the first dielectric layer is in direct contact with a second dielectric layer disposed between two of the plurality of select gate lines;
wherein the semiconductor structure comprises a blocking layer and a semiconductor layer surrounded by the blocking layer, and a portion of the semiconductor layer, at a bottommost end of the semiconductor structure, is within the blocking layer and directly contacts a channel plug of the channel structure; and
wherein the semiconductor layer and the first dielectric layer do not overlap along the first direction.

2. The 3D memory device of claim 1, wherein the channel plug and the semiconductor layer of the semiconductor structure comprise a same material.

3. The 3D memory device of claim 1, wherein the channel plug and the semiconductor layer of the semiconductor structure comprise polysilicon.

4. The 3D memory device of claim 1, wherein the first dielectric layer comprises a zigzag structure in a top plan of the 3D memory device.

5. The 3D memory device of claim 1, wherein the first dielectric layer comprises a waved structure in a top plan of the 3D memory device.

6. The 3D memory device of claim 1, wherein
at least two semiconductor structures are arranged adjacent to each other in a second direction perpendicular to the first direction; and
the at least two semiconductor structures are located between two adjacent first dielectric layers in the second direction.

7. The 3D memory device of claim 1, wherein a width of the semiconductor structure is less than a width of the channel structure.

8. The 3D memory device of claim 1, wherein the first dielectric layer is spaced apart from the plurality of word lines in the first direction.

9. The 3D memory device of claim 1, wherein along the first direction, a sidewall of the first dielectric layer is discontinuously contacted by the plurality of select gate lines, and a first select gate line and a second select gate line of the plurality of select gate lines are disconnected from each other at a location adjacent to the first dielectric layer.

10. The 3D memory device of claim 1, wherein a sidewall of the semiconductor layer is fully surrounded by the blocking layer.

11. The 3D memory device of claim 1, wherein in a plan view, a projection of the first dielectric layer and a projection of the semiconductor layer in the semiconductor structure are non-overlapping.

12. A three-dimensional (3D) memory device, comprising:
a doped semiconductor layer;
a stack structure comprising a plurality of word lines and a plurality of select gate lines formed on the doped semiconductor layer;
a channel structure extending through the plurality of word lines along a first direction and in contact with the doped semiconductor layer;
a plurality of semiconductor structures extending through the plurality of select gate lines along the first direction, and each of the plurality of semiconductor structures is in contact with the channel structure; and
a plurality of first dielectric layers extending through the plurality of select gate lines along the first direction,
wherein a semiconductor structure of the plurality of semiconductor structures comprises a blocking layer and a semiconductor layer surrounded by the blocking layer;
wherein a portion of a sidewall of a first dielectric layer of the plurality of first dielectric layers is in direct contact with a second dielectric layer disposed between two of the plurality of select gate lines;
wherein the plurality of semiconductor structures comprise a first semiconductor structure and a second semiconductor structure arranged adjacent to each other in a second direction perpendicular to the first direction; and
wherein the first and second semiconductor structures are located between two adjacent first dielectric layers of the plurality of first dielectric layers in the second direction.

13. The 3D memory device of claim 12, wherein the first dielectric layer comprises a zigzag structure or a waved structure in a top plan of the 3D memory device.

14. The 3D memory device of claim 12, wherein a width of the semiconductor structure is less than a width of the channel structure.

15. The 3D memory device of claim 12, wherein the first dielectric layer is spaced apart from the plurality of word lines in the first direction.

16. The 3D memory device of claim 12, wherein along the first direction, a sidewall of the first dielectric layer is discontinuously contacted by the plurality of select gate lines, and a first select gate line and a second select gate line of the plurality of select gate lines are disconnected from each other at a location adjacent to the first dielectric layer.

17. The 3D memory device of claim 12, wherein the semiconductor layer and the first dielectric layer do not overlap along the first direction.

18. The 3D memory device of claim 12, wherein a sidewall of the semiconductor layer is fully surrounded by the blocking layer.

19. The 3D memory device of claim 18, wherein the channel structure further comprises a channel plug, and a portion of the semiconductor layer is arranged into the channel plug to be in direct contact with the channel plug at a bottommost end of the semiconductor structure, a sidewall of the portion of the semiconductor layer into the channel plug being surrounded by the blocking layer.

20. The 3D memory device of claim 19, wherein the channel plug and the semiconductor layer of the semiconductor structure comprise polysilicon.
